(19) United States
(12) Patent Application Publication
(10) Pub. No.: US 2011/0139877 A1
(43) Pub. Date: Jun. 16, 2011

(54) Radio Frequency Identification Tag for Use on Metal Objects

(76) Inventors: David C. Szakelyhidi, Windber, PA (US); Michael T. McElhinny, Port Vue, PA (US); Steven J. Fleck, Carnegie, PA (US)

(21) Appl. No.: 12/637,352

(22) Filed: Dec. 14, 2009

(51) Int. Cl. G06K 19/077; H05K 13/04

(52) U.S. Cl. 235/492; 29/825

(57) ABSTRACT

An RFID tag comprises a magnetic core, a wire wrapped around the core, and an integrated circuit electrically connected to the wire. A metal sleeve has an open first end and an open second end opposing the first end. The sleeve further has at least one impediment to the flow of eddy currents, such as a slit, formed between the first and the second ends. An encapsulating/potting material is used to fix the wire wrapped core and the circuit within the sleeve. A method of making such an RFID tag is also disclosed.

### BACKGROUND

The present disclosure is directed generally to radio frequency identification (RFID) tags and, more particularly, RFID tags used in a system to detect the presence of items carrying such a tag.

RFID systems are comprised of two components—the tag, sometimes called a transponder, and a reader, sometimes called an interrogator. The tag acts as a programmable data storage device. The reader establishes a wireless communication link with the tag and reads the data stored in the tag. Both the reader and the tag have an antenna for communicating with one another.

There are many different ways to categorize RFID systems available today. One way to categorize systems is based on the type of antenna that is used in the tag. One type of antenna is disc-shaped and uses a circularly wound coil while another type is cylindrically shaped and uses a wire wound around a rod shaped ferrite core. The ferrite core may also be rectangular. Another way to categorize systems it to distinguish between passive systems which use a tag that relies on power harvested from the field created by the reader and antenna or the field in the environment, versus active systems in which the tag contains a power source such as a battery. Passive systems may be further categorized as near field systems that inductively couple to the reactive energy circulating around the reader's antenna and far field systems that couple to the radiated power contained in electromagnetic waves propagating in free space from the antenna of the reader. Systems can be categorized according to the frequency at which they operate. Two common frequencies of operation are 125 kHz and 13.56 MHz. Another way to categorize RFID systems is based on the communication scheme by which the tag and reader talk to one another. Regardless of these various ways of categorizing RFID systems, there are some fundamental principles that RFID systems must follow. One of those principles, described below, is that for maximum coupling between the tag and the reader, the tag should act as a resonant circuit that resonates at the operating frequency of the reader.

For lower frequencies such as 125 kHz and 13.56 MHz, the coupling between an RFID tag and reader is similar to the inductive coupling between the primary winding of a transformer and the secondary winding of the transformer. When the antenna connected to the reader (which in most cases is much larger than the antenna of the tag) is energized with an alternating current, an alternating magnetic field is created around the antenna. When an RFID tag is brought within this magnetic field, the antenna of the tag extracts energy from the magnetic field set up by the reader. Generally, the larger the tag antenna, the more energy that can be extracted from the magnetic field. Maximum coupling occurs when the tag resonates at the frequency of operation, e.g., 125 kHz or 13.56 MHz. Designing a tag that will resonate at the frequency of operation is based upon the following known equation:

resonant frequency=1/(2Π\sqrt{LC}) (1)

Equation (1) relates the resonate frequency (e.g , 125 kHz or 13.56 MHz) to the values of inductance (L) and capacitance (C) of the tag antenna. The values of the inductance and capacitance of the tag antenna are known based on the physical characteristics of the antenna and chip capacitance. It is common for the inductance and capacitance of the tag antenna to not satisfy equation (1), so often a capacitor is added to the antenna circuit to cause equation (1) to be satisfied. Also, the number of coil turns may be adjusted thus adjusting the value of (L). When the values of (L) and (C) are fixed so that equation (1) is satisfied, the tag is said to be tuned, and the capacitor added to the antenna circuit is sometimes referred to as a tuning capacitor. Often, this capacitance is integrated into the integrated circuit chip.

Although the tuning of a tag may seem to be a straight forward matter, uncertainties caused by environmental conditions or a changing environment can quickly cause problems. For example, it is known that metals reflect higher frequency signals e.g., 13.56 MHz, to a greater extent than lower frequency signals e.g., 125 kHz. Metals also cause eddy currents, electrical currents flowing in the metal adjacent to a magnetic field. These eddy currents dissipate power meaning there is less power available for the tag. Finally, the proximity of metal causes the stray capacitance in the system to change from the value of the stray capacitance without the metal present, causing the tag to become detuned. One example is the interwinding capacitance in the tag antenna. Metal in close proximity to the tag antenna will change the capacitance and therefore the tuning. All of these effects reduce the distance at which a reader can detect a tag and interfere with the communication between the reader and the tag. Added to those problems is the fact that metal objects are often big and heavy compared to the size and weight of an RFID tag, and metal objects are often subjected to extremely harsh environments, such as a sterilizing environment. As a result, the use of RFID tags on metal objects is very problematic.

The work by Senba et al. attempts to address some of these problems. For example, U.S. Pat. No. 6,897,827 issued May 24, 2005 and entitled Installation Structure for RFID Tag, Method for Installing RFID Tag, and Communication Using Such RFID Tag discloses an RFID tag installing structure for installing a microminiaturized RFID tag having a cylindrical antenna coil to a conductive member. An RFID tag having a cylindrical antenna coil and shaped into a rod is installed such that the axial direction of the RFID tag is parallel to the installation surface composed of the bottom surface of an installation groove made in a conductive member and is in contact with the installation surface.

Another patent to Senba et al., U.S. Pat. No. 6,927,738 issued Aug. 9, 2005 and entitled Apparatus and Method for a Communications Device, discloses a sheet-like amorphous magnetic material being arranged in a manner extending from a magnetic flux generating portion of a concentric disk-shaped antenna coil of an RFID tag serving as the communication device to an outer area of the antenna coil.

Yet another patent to Senba et al., U.S. Pat. No. 7,088,249 issued Aug. 8, 2006 and entitled Housing Structure for RFID Tag, Installation Structure for RFID Tag, and Communication Using Such RFID Tag, discloses providing a novel installation structure for an RFID tag, which effectively protects the RFID tag from external stress or impact during the storage, transportation and usage, and allows communication with an external device. The '249 patent also discloses providing a novel installation structure for an RFID tag, which enables communication with the external device even if the RFID tag is installed on a conductive member such as a metal member, and the surface thereof is covered with a protective member typically made of a metal which has an excellent strength and durability. The '249 patent also discloses providing a communication method using an RFID tag surrounded by a conductive member typically made of a metal. Even if an RFID tag is housed in a container typically made of a conductive material such as a metal having a large mechanical strength, the RFID tag can communicate with an external read/write terminal as mediated by leakage magnetic flux if only a flux leakage path composed for example of a gap is formed in such container.

U.S. Pat. No. 3,594,805 is directed to aerials comprising a ferrite rod disposed within a longitudinally split sleeve of electrically conducting material and where a substantially uniform capacitance exists or is provided across the split. According to this invention, the resonant frequency of the aerial can be adjusted by varying the inductance of the split sleeve disposed around the ferrite rod.

Although work has been done toward providing RFID tags that can be used to tag and track metal items, tag-to-tag coupling of closely spaced tags, detuning, and physical damage remain serious issues. Thus, a need exists for a rugged, economical RFID tag that can remain tuned when attached to metal objects or brought into close contact with other tags and can work in an environment containing large numbers of metal objects while maintaining maximum read distances and high signal to noise ratios for the received communications.

### SUMMARY

The present disclosure is directed to an RFID tag comprising a magnetic core, a wire wrapped around the core, and an integrated circuit electrically connected to the wire. A metal sleeve has an open first end and an open second end opposing the first end. The sleeve further has at least one impediment to the flow of eddy currents formed between the first and the second ends. The impediment may take a virtually infinite number of forms including various types and combinations of slits, non contacting but overlapping sections (edges) of the sleeve, perforations, or nonmagnetic or nonmetallic portions formed in the sleeve. An encapsulating/potting material is used to fix the wire wrapped core and the circuit within the sleeve, while preventing electrical contact of the coil circuit with the metal sleeve.

The present disclosure is also directed to a method of constructing an RFID tag, comprising: winding a wire about a core; connecting an integrated circuit to the wire; inserting the wire wound core and circuit into a metallic sleeve having open opposing ends and at least one impediment to the flow of eddy currents formed between the open opposing ends; and fixing the wire wound core and circuit within the metallic sleeve. The method can include connecting an optional tuning capacitor if needed, or means to tune coil inductance.

The RFID tag disclosed herein has many benefits. The metal sleeve creates a known electrical environment for the RF components of the tag that effectively isolates the RF components from the environment outside of the sleeve and allows the resonant frequency to remain stable. A primary factor of this environment is the inter-winding capacitance. This is what is believed will change when a prior art tag is brought near metal. Bringing metal nearby a prior art tag also adds resistance, or loss, into the overall system. The end result of such effects is a shift in tuning which then makes the prior art tag resonate at a different frequency than the frequency at which the reader is designed to communicate. The observed effect on a prior art tag is therefore a drastic reduction in read range or the complete inability to read a tag when the tag is very near metal. Another benefit of the metal sleeve isolating the RF components from the environment is that the tags are not de-tuned when brought into close proximity of other RFID tags (including other like tags). This is distinct from the benefit of not detuning around metal. Coupling and subsequent detuning of tags that are closely packed into a volume is a common problem in RFID system design. Another benefit of the RFID tag disclosed herein is that the impediment (e.g., slit) in the metal sleeve stops eddy currents which can cause power and signal losses. This encapsulated, metallic sleeve configuration with the air gap is a novel form factor. Those advantages and benefits, and others, will be apparent from the detailed description below.

### BRIEF DESCRIPTION OF THE DRAWINGS

For the present disclosure to be easily understood and readily practiced, preferred embodiments will now be described, for purposes of illustration and not limitation, in conjunction with the following figures.

FIGS. 1A-1D illustrate, respectively, a ferrite core, a coil wound around the ferrite core and a chip and tuning capacitor attached to the coil, a metal sleeve, and a finished RFID tag according to one embodiment of the present disclosure.

FIG. 2 illustrates the finished tag of FIG. 1D mounted on a metallic item.

FIGS. 3A-3D illustrate, respectively, a ferrite core, a coil wound around the ferrite core and a chip attached to the coil, a metal sleeve, and a finished RFID tag according to another embodiment of the present disclosure.

FIG. 4 illustrates the finished tag of FIG. 3D mounted on a metallic item.

FIG. 5A is a cross-sectional, cutaway, perspective view of a finished RFID tag of the type shown in FIG. 3D while FIGS. 5B, 5C, and 5D illustrate side, top, and frontal views, respectively, of the finished tag.

FIGS. 6A and 6B illustrate other embodiments of a sleeve which may be used in the present invention.

FIG. 7 is a flow chart illustrating a method of constructing a finished tag according to the present disclosure.

FIG. 8 illustrates a best case vertical read range, when interrogated with an inductive loop reader antenna.

FIG. 9 illustrates a best case horizontal read range, when interrogated with an inductive loop reader antenna.

FIG. 10 illustrates the side-by-side stacking of tagged metal instruments in a metal tray.

FIGS. 11A and 11B illustrate electrical and mechanical methods, respectively, of effectively “shutting off” the tag, temporarily or permanently.

FIG. 12 is an end view of a metal sleeve having edges configured to control (minimize) the capacitance therebetween.

FIGS. 13A, 13B, and 13C illustrate a device similar to the device shown in FIGS. 1A-1D but without the RFID chip, suitable for electronic article surveillance systems (EAS).

### DETAILED DESCRIPTION

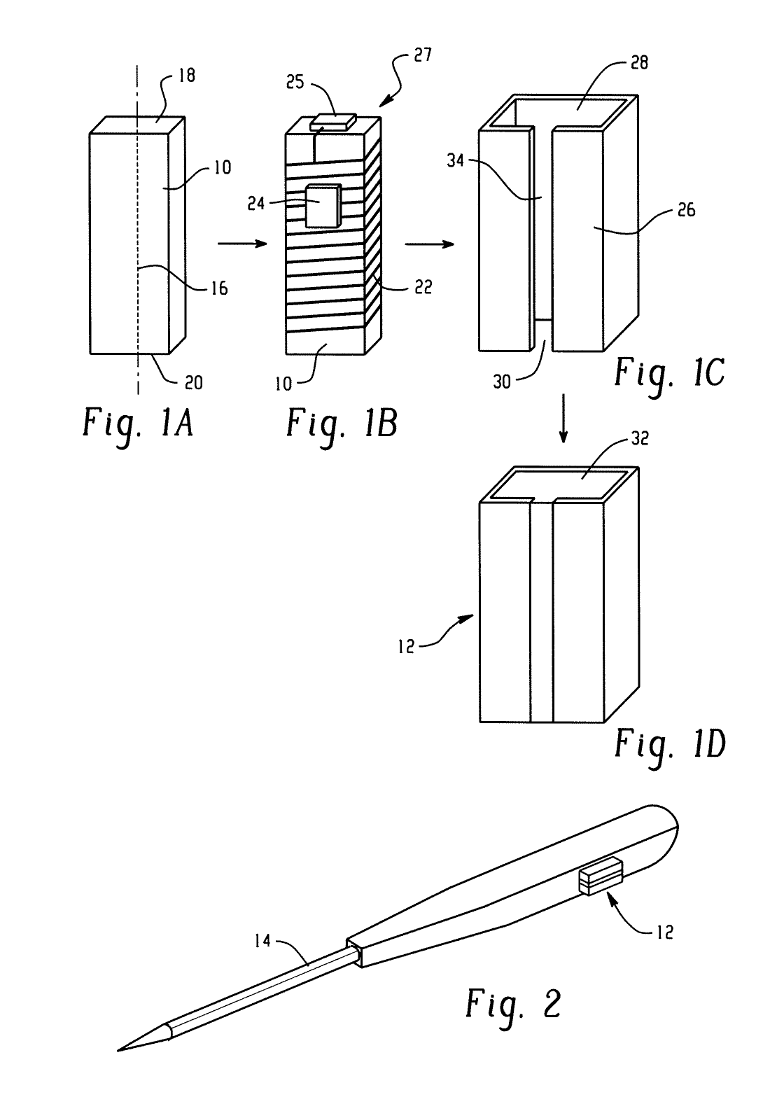

Turning now to FIGS. 1A-1D, those figures illustrate one embodiment of the present invention beginning with, in FIG. 1A, a flat rectangular ferrite core 10 and ending in FIG. 2 with a finished tag 12 connected to an instrument 14. Returning to FIG. 1A, the core 10 may be constructed of any magnetizable material. Additionally, the core 10 may come in a variety of shapes, sizes, and permeabilities, as will be readily apparent to those of ordinary skill in the art. The core 10 generally defines a longitudinal axis 16 having a first end 18 and a second end 20, with the ends 18 and 20 being opposed to one another.

As shown in FIG. 1B, a wire 22 is wound around the core 10. An RFID chip 24 is electrically connected to the wire 22. The chip 24 may be a commercially-available chip such as the SLi-L available from NXP of the Netherlands. An optional tuning capacitor 25 may also be electrically attached to the wire 22.

The combination 27 of the RFID chip 24, the wire 22 wrapped core 10, and optional tuning capacitor 27 is inserted into a metal sleeve 26 shown in FIG. 1C. The metal sleeve 26 has an first open end 28 and a second open end 30 generally positioned opposite to, or opposing, the first open end 28. Those skilled in the art will recognize that the combination 27 is inserted into the metal sleeve 26 such that the first and second opposing ends 18 and 20 of the longitudinal axis 16 are positioned to correspond to the first open end 28 and the second open end 30 of the metal sleeve 26, respectively. After the combination 27 is inserted into the metal sleeve 26, a potting or encapsulation material is added, as shown in FIG. 1D to fix the various components so that they are unable to move within the metal sleeve 26. Thereafter, the finished tag 12 may be attached to a metallic device such as, for example, the surgical instrument 14 illustrated in FIG. 2. The finished tag 12 may be welded, bonded, or fixed in any convenient manner to the instrument 14. After attachment to the surgical instrument 14, the finished RFID tag 12 is sterilizable (autoclave or EtO). Note that in this embodiment, the metal sleeve 26, because of its rectangular shape, presents flat sides for contacting the instrument 14.

In one embodiment, the finished RFID tag 12, sometimes referred to as a transponder, is designed to operate at a 13.56 MHz frequency or other frequencies which use inductive coupling for communications and energy transfer, for use on metal instruments, such as instrument 14 shown in FIG. 2, or in varying environments which could affect the tuning of the finished tag 12. In one embodiment, the metal sleeve 26 is comprised of stainless steel. The RFID tag is designed to be attached to surgical instruments and therefore is designed to withstand the harsh environments encountered during sterilization.

The sleeve 26 preferably has a complete air gap or slit 34 running lengthwise from the first open end 28 to the second open end 30 although there are infinite patterns of slits that could work. Because the slit doesn't need to be straight, the slit could be wavy, an “interlocking finger” pattern, etc. There could also be overlapping edge portions with vertical separation between layers such that from the outside looking at the tag, it might appear to have no slit. (See FIG. 6B) These design choices could be driven by cost, ease of manufacture, structural strength, etc.

The dimensions of the slit are preferred to be a small percentage of the circumference of the tag. The prototypes we have tested have a slit having a width that is 15% of the circumference of the metal sleeve. We believe slits anywhere from 1-25% will work, with 15% being a presently preferred embodiment. Slits of a width that is above 25% of the circumference of the sleeve may result in diminishing effectiveness of the slit.

Other methods may be used to reduce the effects of eddy currents while still providing the benefits of a consistent electrical background. One other method contemplates using a perforated metal sleeve. Another method contemplates the use of a sleeve having non-metallic regions interspersed through out the sleeve. (See FIG. 6A) Other designs may be envisioned with multiple slits. A one-slit design facilitates manufacturing because it can be produced with a rolled metal sheet. However multiple slit designs are valid as well, so long as the capacitance effect (discussed below) is considered, and the total area of the slits should follow the guideline of slit/circumference ratio discussed above.

Consideration should be given to the detail around the slit, in particular the width of the slit and the cross-section of the sleeve material. The two side walls of the slit, brought very near to each other, could create a capacitance that would allow for current to flow. At the intended frequencies of operation, the slit would need to be extremely narrow for capacitance to begin to have an effect. We believe that the slit size would be within the tolerance of most production equipment, so the mere act of designing a slit that can be manufactured would eliminate designs where capacitance is an issue. Also realize that the sleeve thickness can be adjusted without consequence, as long as a thickness greater than the electrical skin depth is maintained.

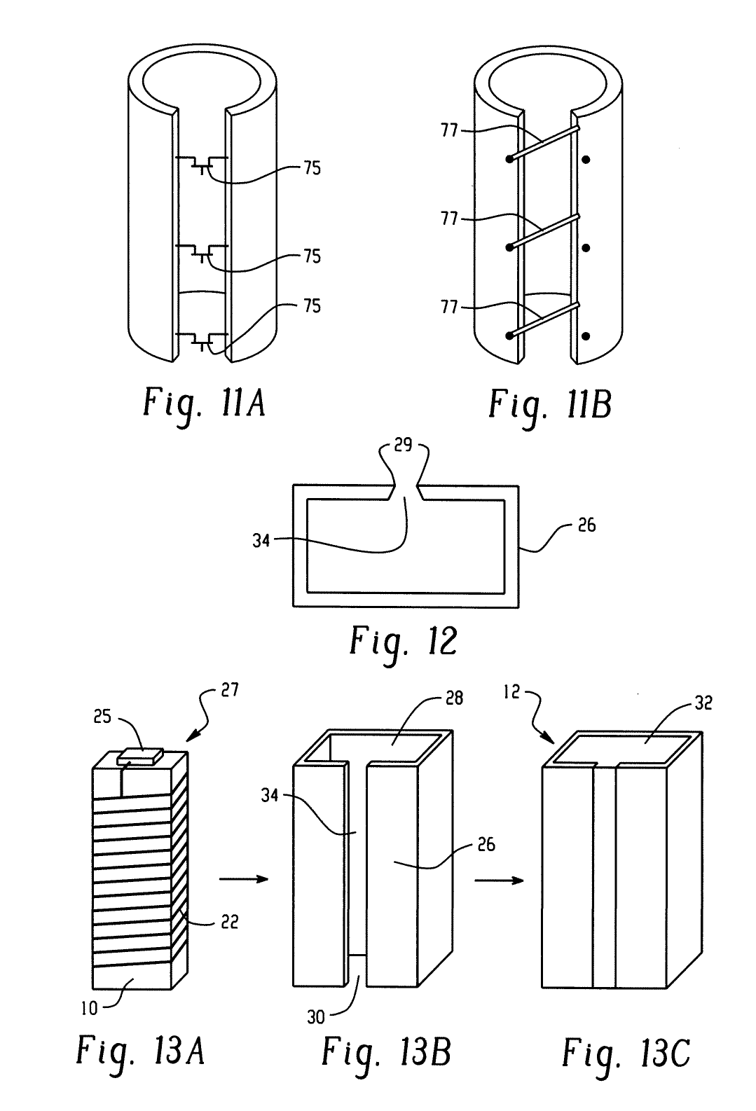

There may be some designs that result in some capacitance across the slit. By controlling the configuration of the edges 29 of the sleeve 26 at the slit 34 as shown in FIG. 12, the capacitance can be controlled. For example, capacitance could be reduced by tapering the cross-section of the sleeve wall such that the surface areas of the two sides of the sleeve that are adjacent is very small. That would reduce capacitance because surface area is in direct proportion to capacitance.

It is believed that the longitudinal slit 34 running from the first open end 28 to the second open end 30 presents an impediment or barrier to the flow of eddy currents. The purpose of the metal sleeve 26 is to provide a large metal presence which controls the tuning of the finished tag 12. Once the finished tag 12 is tuned, placing the finished tag 12 in the presence of metallic objects does not detune the finished tag 12 because it is believed that the presence of the metal objects is inconsequential due to the close proximity of the metal sleeve 26 in conjunction with the combination 27. In effect, the metal sleeve 26 isolates the RFID chip 24 from the environment outside of the sleeve 26. The wire 22 forms a coil which is tuned (perhaps with the aid of a tuning capacitor or by controlling the number of windings) to interact with only the magnetic sleeve 26 such that any additional metal next to the outside of the sleeve 26 does not disturb the interwinding capacitance which will disturb the resonant frequency of the tuned tag 12.

A benefit of using some type of slit over other types of impediments is that we can leverage the concept of the slit to create a “switchable” RFID tag. By physically closing the slit, either by directly pushing or squeezing the sleeve until the slit is closed, or by closing a jumper circuit or electrical switch (see FIG. 11A having a plurality of transistors 75), or by adjusting mechanical members (see FIG. 11B having a plurality of movable arms 77), one could effectively “shut off” the tag temporarily or permanently. By utilizing metal having a strong memory or other metals that respond to environmental factors such as temperature, it is possible to make an RFID tag that switches itself on/off based on external factors. For example, a range of tags could be made each with slightly different response to temperatures. While RFID tags with temperature sensors exist, those rely on solid state or MEMS technology. RFID tags of the present disclosure would be a low cost analog solution.

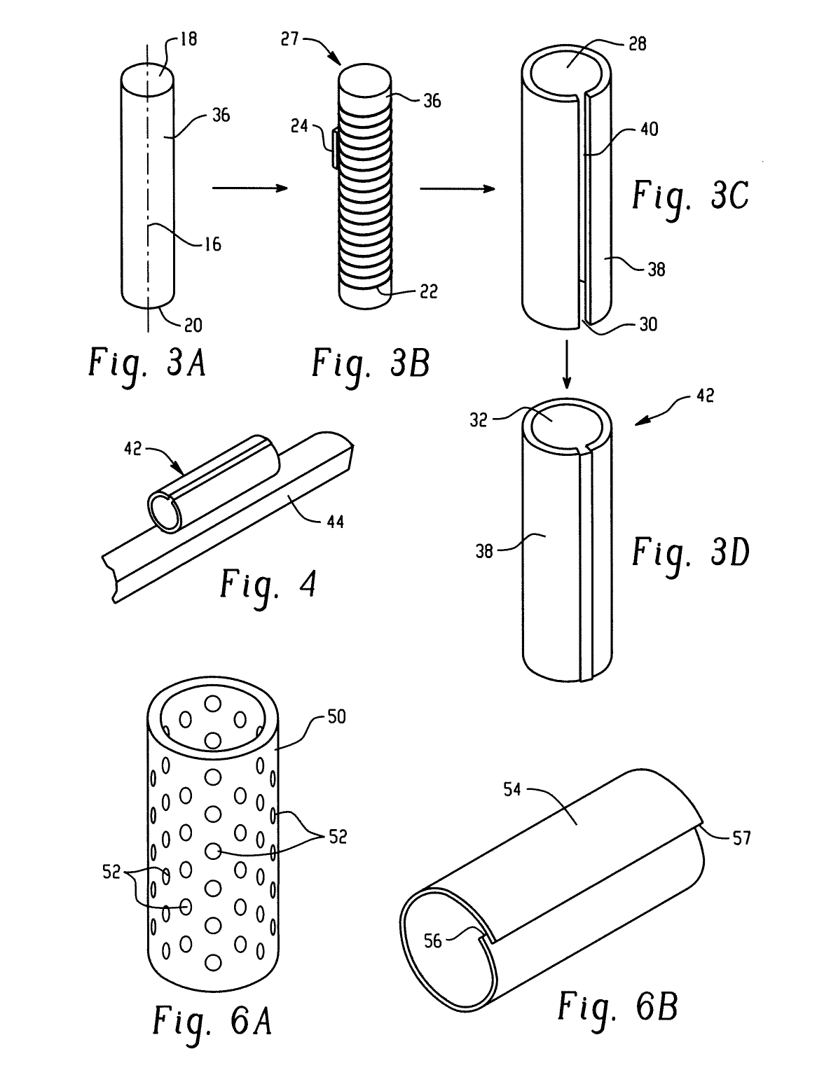

Another embodiment of the present invention is disclosed in FIGS. 3A-3D which illustrate, respectively, a cylindrical ferrite core 36 defining a longitudinal axis 16 having first and second opposing ends 18 and 20, respectively. Where appropriate, reference numbers used in the description of the embodiment of FIGS. 1A-1D are reused to identify like components in the description of the embodiment shown in conjunction with FIGS. 3A-3D. In FIG. 3B, a wire 22 has been wrapped around the ferrite core 36 and an RFID chip 24 is electrically connected to the wire 22. Thereafter, the combination 27 is inserted into a cylindrically shaped metal sleeve 38 having a first open end 28 and a second open end 30. The cylindrical metal sleeve 38 has a slit 40 extending from the first open end 28 to the second open end 30. Thereafter, as shown in FIG. 3D, a potting or encapsulating material 32 is added to fix the components to produce the finished tag 42. The finished tag 42 may be affixed by any suitable means to metal instrument 44. Although not shown in the figures, the outer surface of the sleeve 38 may be flattened in an area to provide for a more secure attachment to the instrument 44.

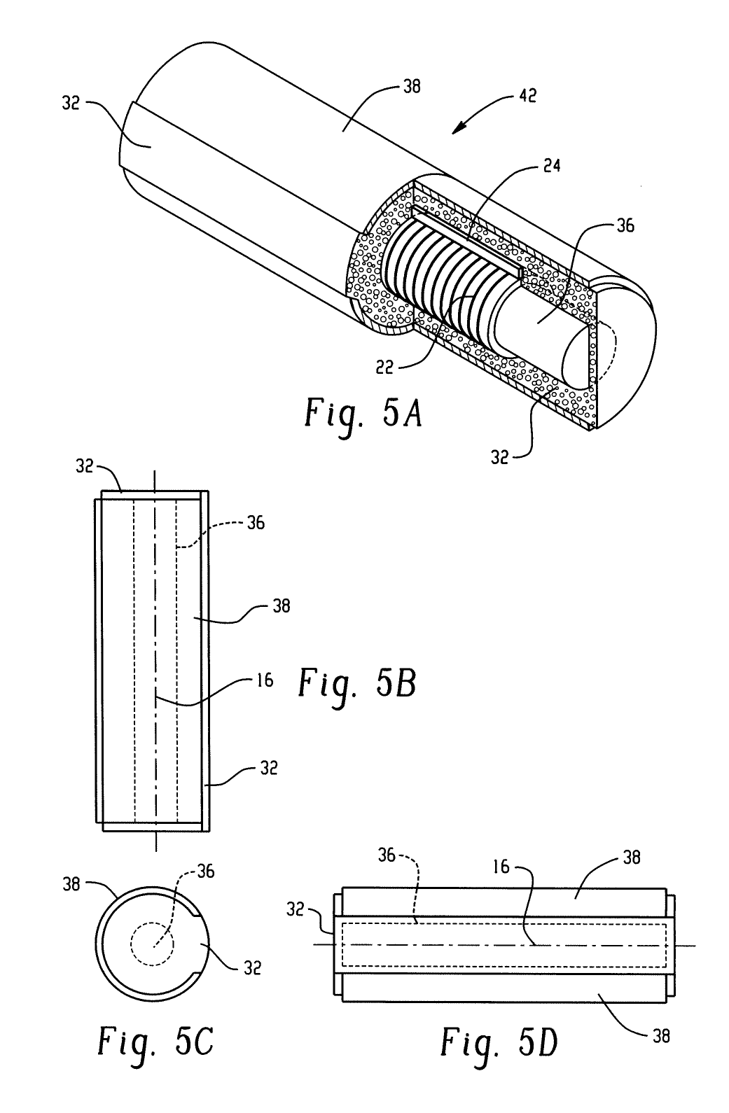

A closer look at the finished tag 42 shown in FIG. 3D is provided in FIG. 5A which is a cross-sectional, cutaway, perspective view of the finished RFID tag 42 and FIGS. 5B, 5C, and 5D which illustrate side, top, and frontal views, respectively, of the finished tag 42. The frontal view is defined as the view looking directly at the epoxy filled slit 40. All dimensions are in inches. The thickness of the sleeve is, for the most part, chosen for mechanical integrity such as rigidity of the tag. There really is no maximum thickness, but the minimum is based on skin depth. If the metal is so thin that it is physically smaller than a skin depth, effects from the environment may become evident again. In most cases, the skin depth is so thin that it would make manufacturing quite difficult. Because the shape of the interior of the sleeve 38 is symmetrical, positioning of the combination 27 within the sleeve 38 during manufacturing is somewhat forgiving. If the combination 27 is placed off-center, the combination 27 will be affected more by the metal on one side, but less by the metal on the other side. Therefore the small affects of off-center placement are negated by the symmetry of the sleeve 38. This benefit is also true for the sleeve 26 of FIG. 1C.

As will be apparent from the foregoing description of the embodiments of the present invention, the particular shape or configuration of the ferrite cores 10, 36 is not critical to the operation of the present invention. Furthermore, the particular shape or configuration of the metallic sleeves 26, 38, whether square, rectangular, or circular, among others, is not critical to the operation of the present invention. Providing the metal sleeve with a slit provides a means for the flux lines of the ferrite core to complete their electromagnetic circuit and maintain optimal readability. Although the slits illustrated in the embodiments discussed above extend perpendicularly from one open end to the other open end of the sleeve, the slits may extend at an angle. Other types of discontinuities or impediment to the flow of eddy currents may also be used as discussed above and as shown in FIG. 6A which illustrates a sleeve 50 having a plurality of nonmagnetic portions or perforations 52. Another embodiment of a sleeve 54 is shown in FIG. 6B in which non contacting but overlapping sections, edges 56 and 57 of the sleeve, form the slit.

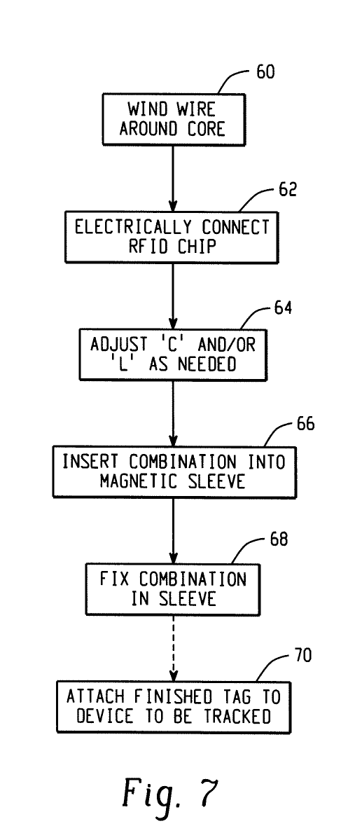

Turning now to FIG. 7, FIG. 7 is a flowchart illustrating the steps for constructing an RFID tag according to the present disclosure. In FIG. 7, at 60, the wire is wound around the core. At 62, the RFID chip is electrically connected to the wire. At 64, the combination of the RFID chip and the wire-wrapped core are tested, and a tuning capacitor is added, as needed, to achieve the proper resonant frequency, taking into account the detuning anticipated after the combination of the RFID chip, tuning capacitor, and wire-wrapped core are inserted into the metal sleeve. Alternatively, or in addition to, the inductance of the winding may be adjusted by changing the number of windings of the wire around the core. In other words, the combination of the RFID chip and the wire-wrapped core are detuned at step 64, such that when the combination is inserted into the metal sleeve, the effect of the metal sleeve will cause the finished tag to be properly tuned. After the capacitance, inductance, or both are adjusted at 64, as needed, the combination is inserted into the metal sleeve at 66. After insertion, a potting material is added at 68 to keep the combination of the RFID chip, wire wound core, and tuning capacitor, if any, fixed within the metal sleeve. The finished tag may then be attached at 70 to a device to be tracked. It is anticipated that the finished tags will be used in combination with the tracking of metal devices, such as surgical instruments. The finished tags may be welded, bonded, or affixed in any convenient manner at 70 to the device to be tracked.

Readability testing was performed using the following equipment and settings:
Instrument Scanning Wand
   5.5 inch diameter, 2 turn, 12 AWG antenna
   FEIG static antenna tuning board set to 1 Ohm
   1.35 m coaxial cable length between the LRM2000 and tuning board
FEIG LRM2000
   Varying power levels
Tagged Instruments
   3 hemostats (small, med, large) w/metal sleeve tag
   Small SS tray w/metal sleeve tag
   Existing Tagsys™ sponge tag

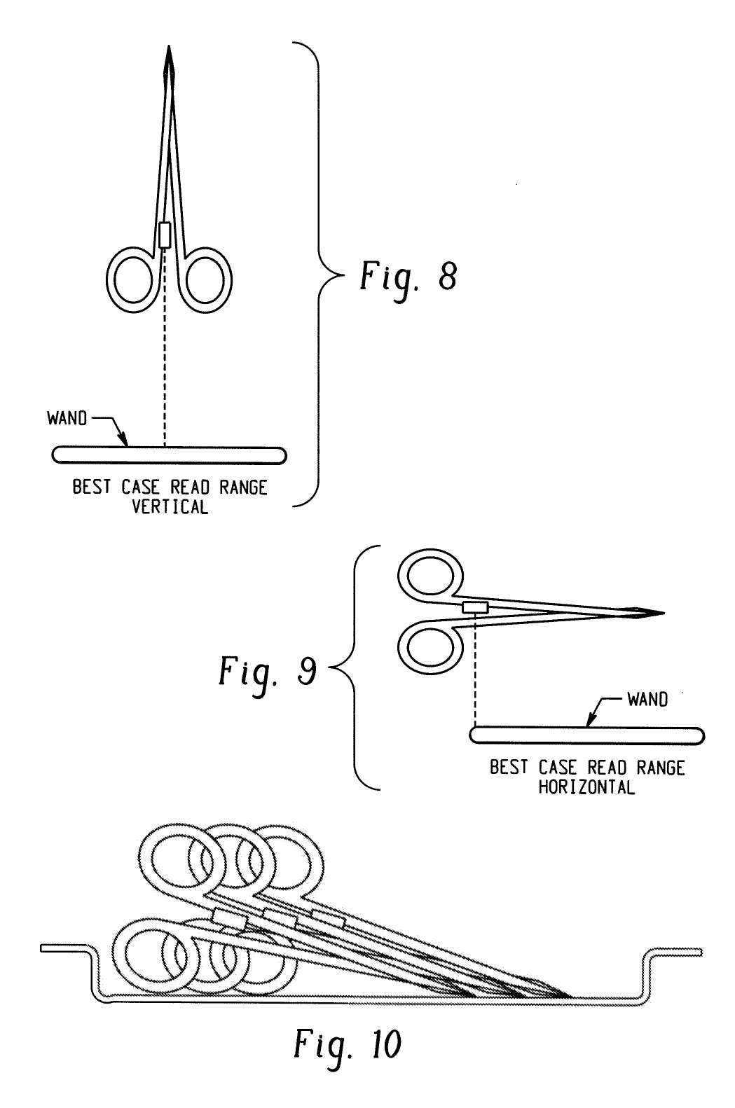

As the instrument wand (reading antenna) is swept over the tag, there exists a best case read range for tags positioned vertically with respect to the reading antenna as shown in FIG. 8 and positioned horizontally with respect to the reading antenna a shown in FIG. 9. It was seen that horizontal best read range is approximately 70% of vertical best read range. Also, read range was not diminished when metal instruments were stacked side by side in a metal tray as shown in FIG. 10.

The read range was tested for three tag types, commercially available Tagsys™ sponge tags, the RFID tags of the present disclosure by themselves, and the RFID tags of the present disclosure attached to metal instruments. These tests were done using the best case vertical read range (see FIG. 8) for the RFID tags of the present disclosure and best case coaxial alignment (See FIG. 9) for the Tagsys™ tags. Results are shown in the following table.

| | | | Read Range | Read range | |
|---|---|---|---|---|---|
| R (ohms) | Q | Power (W) | (in) vert | (in) horiz | Tag Type |
| 2 | 17 | 2 | 7.25 | — | Tagsys tag |
| 2 | 17 | 2 | 5.75 | 4 | Metal Sleeve |
| 2 | 17 | 2 | 5.75 | 4 | Metal Sleeve |
| | | | | | w/instrument |
| 2 | 17 | 4 | 8.5 | — | Tagsys tag |
| 2 | 17 | 4 | 6.625 | 4.6 | Metal Sleeve |
| 2 | 17 | 4 | 6.625 | 4.6 | Metal Sleeve |
| | | | | | w/instrument |
| 2 | 17 | 6 | 9 | — | Tagsys tag |
| 2 | 17 | 6 | 7.125 | 5 | Metal Sleeve |
| 2 | 17 | 6 | 7.125 | 5 | Metal Sleeve |
| | | | | | w/instrument |
| 2 | 17 | 8 | 9.5 | — | Tagsys tag |
| 2 | 17 | 8 | 7.5 | 5.25 | Metal Sleeve |
| 2 | 17 | 8 | 7.5 | 5.25 | Metal Sleeve |
| | | | | | w/instrument |

It can be seen that there is no difference in read range when a tag is welded to a metal instrument. There is a 1.75 inch increase in read range if reader power is increased from 2 W to 8 W. It is possible to run this wand using a low power, if maximum read range is not required. This reduction to practice of the invention can effectively allow reading of tagged surgical items, even when in a metal tray, from at worst case, four inches away when using lowest reader power settings. This reduction to practice could be optimized further by improving reader antenna and detection characteristics.

Turning now to FIGS. 13A-13C, these figures illustrate a tag suitable for use in EAS applications. FIGS. 13A-13C correspond to FIGS. 1B-1D, respectively, and illustrate the same tag and tag construction but without the RFID chip 24.

While the disclosure has been described in detail and with reference to specific embodiments thereof, it will be apparent to one skilled in the art that various changes and modifications can be made therein without departing from the spirit and scope of the embodiments. Thus, it is intended that the present disclosure cover the modifications and variations of this disclosure provided they come within the scope of the appended claims and their equivalents.

What is claimed is:

1. An RFID tag comprising:
a magnetic core;
a wire wrapped around said core;
an integrated circuit connected to said wire;
a metal sleeve having an open first end and an open second end opposing said first end, said sleeve further having at least one impediment to the flow of eddy currents formed between said first and said second ends; and
an encapsulating material for fixing said wire wrapped core and said circuit within said sleeve.

2. The RFID tag of claim 1 wherein said sleeve comprises one of a square, rectangular, or circular sleeve.

3. The RFID tag of claim 2 wherein said at least one impediment comprises a slit running longitudinally from said first open end to said second open end.

4. The RFID tag of claim 3 wherein said slit runs either perpendicularly or angularly from said first open end to said second open end.

5. The RFID tag of claim 3 wherein edges of said slit are configured to control capacitance therebetween.

6. The RFID tag of claim 3 wherein said sleeve is comprised of temperature sensitive material such that a dimension of said slit is responsive to temperature.

7. The RFID tag of claim 3 wherein said sleeve is constructed of a material that has a memory.

8. The RFID tag of claim 3 additionally comprising a member for bridging said slit.

9. The RFID tag of claim 1 wherein said at least one impediment comprises a plurality of discontinuities in said sleeve.

10. The RFID tag of claim 9 wherein said discontinuities comprise either openings, nonmetallic, or nonmagnetic portions formed in said sleeve.

11. The RFID tag of claim 1 wherein said integrated circuit comprises one of an actively powered or a passive integrated circuit.

12. An RFID tag comprising:
a ferrite core defining a longitudinal axis;
a wire wrapped around said core;
an integrated circuit electrically connected to said wire;
a metal sleeve having an open first end and an open second positioned at opposing ends of said longitudinal axis, said sleeve further having at least one slit extending from said first end to said second end; and
an encapsulating material for fixing said wire wrapped core and said circuit within said sleeve.

13. The RFID tag of claim 12 wherein said sleeve has a symmetrical configuration.

14. The RFID tag of claim 12 wherein a width of said slit is from 1% to 25% of the circumference of said sleeve.

15. The RFID tag of claim 12 wherein edges of said slit are configured to control capacitance therebetween.

16. The RFID tag of claim 12 wherein said sleeve is comprised of temperature sensitive material such that a dimension of said slit is responsive to temperature.

17. The RFID tag of claim 12 wherein said sleeve is constructed of a material that has a memory.

18. The RFID tag of claim 12 additionally comprising a member for bridging said slit.

19. The RFID tag of claim 1 wherein said integrated circuit comprises one of an actively powered or a passive integrated circuit.

20. A tag comprising:
a magnetic core;
a wire wrapped around said core;
a metal sleeve having an open first end and an open second end opposing said first end, said sleeve further having at least one impediment to the flow of eddy currents formed between said first and said second ends; and
an encapsulating material for fixing said wire wrapped core and said circuit within said sleeve.

21. A method of constructing an RFID tag, comprising:
winding a wire about a core;
connecting an integrated circuit to said wire;
inserting said wire wound core and circuit into a metallic sleeve having open opposing ends and at least one impediment to the flow of eddy currents formed between said open opposing ends; and
fixing the wire wound core and circuit within the metallic sleeve.

22. The method of claim 21 additionally comprising connecting a tuning capacitor to said wire.

23. The method of claim 21 additionally comprising adjusting the number of times said wire is wound around said core.
